(19) United States
(12) Patent Application Publication
(10) Pub. No.: US 2025/0105200 A1
(43) Pub. Date: Mar. 27, 2025

(54) POWER MODULE STRUCTURE WITH CLIP SUBSTRATE MEMBER

(71) Applicant: SEMICONDUCTOR COMPONENTS INDUSTRIES, LLC, Scottsdale, AZ (US)

(72) Inventors: Seokbong KIM, Paju-si (KR); Byoungok LEE, Yeonsu-gu (KR); Yong LIU, Cumberland Foreside, ME (US)

(73) Assignee: SEMICONDUCTOR COMPONENTS INDUSTRIES, LLC, Scottsdale, AZ (US)

(21) Appl. No.: 18/473,998

(22) Filed: Sep. 25, 2023

(51) Int. Cl. H01L 23/00; H01L 25/00; H01L 25/07

(52) U.S. Cl. CPC H01L 24/41; H01L 24/05; H01L 24/06; H01L 24/29; H01L 24/32; H01L 24/37; H01L 24/38; H01L 24/40; H01L 24/73; H01L 24/84; H01L 24/92; H01L 25/072; H01L 25/50; H01L 2224/05568; H01L 2224/05638; H01L 2224/06181; H01L 2224/2919; H01L 2224/29191; H01L 2224/32225; H01L 2224/32237; H01L 2224/3701; H01L 2224/38; H01L 2224/40139; H01L 2224/41175; H01L 2224/73263; H01L 2224/84051; H01L 2224/92246; H01L 2924/01014; H01L 2924/0665; H01L 2924/07025; H01L 2924/0715; H01L 2924/13055; H01L 2924/13091

(57) ABSTRACT

A power module includes a substrate, a plurality of semiconductor dies coupled to the substrate, and a clip substrate member having a first surface and a second surface. The first surface is coupled to the plurality of semiconductor dies. The clip substrate member includes a first conductive clip, and a second conductive clip, and a dielectric material portion disposed between the first conductive clip and the second conductive clip. The second surface includes a first contact region and a second contact region. The first contact region includes a portion of the first conductive clip. The second contact region includes a portion of the second conductive clip.

### BACKGROUND

Multiple clips may be used in a power module to connect power components and/or to transfer heat away from the power components. However, conventional clip structures may increase module size and/or cause alignment issues during the manufacturing process, thereby causing longer processing times.

### SUMMARY

In some aspects, the techniques described herein relate to a power module including: a substrate; a plurality of semiconductor dies coupled to the substrate; and a clip substrate member having a first surface and a second surface, the first surface being coupled to the plurality of semiconductor dies, the clip substrate member including a first conductive clip, and a second conductive clip, and a dielectric material portion disposed between the first conductive clip and the second conductive clip, the second surface including a first contact region and a second contact region, the first contact region including a portion of the first conductive clip, the second contact region including a portion of the second conductive clip.

In some aspects, the techniques described herein relate to a power module including: a substrate including a first conductive layer, a second conductive layer, and a dielectric layer disposed between the first conductive layer and the second conductive layer; a plurality of semiconductor dies coupled to the first conductive layer of the substrate; and a clip substrate member including a first conductive clip coupled to the plurality of semiconductor dies, a second conductive clip coupled to the plurality of semiconductor dies, and a dielectric material having a portion disposed between the first conductive clip and the second conductive clip, the clip substrate member including a source contact region, the source contact region including a first portion of a surface of the clip substrate member, the source contact region including a portion of the first conductive clip.

In some aspects, the techniques described herein relate to a method of assembling a power module, the method including; assembling a clip substrate member, the clip substrate member including a first conductive clip, a second conductive clip, and a dielectric material having a portion disposed between the first conductive clip and the second conductive clip, the clip substrate member including a first surface and a second surface; coupling a plurality of semiconductor dies to a conductive layer of a substrate; and coupling the clip substrate member to the plurality of semiconductor dies such that the plurality of semiconductor dies is coupled to the first conductive clip and the second conductive clip.

The details of one or more implementations are set forth in the accompanying drawings and the description below. Other features will be apparent from the description and drawings, and from the claims.

### BRIEF DESCRIPTION OF THE DRAWINGS

FIG. 1A illustrates a side view of a power module with a clip substrate member according to an aspect.

FIG. 1B illustrates a side view of the clip substrate member according to an aspect.

FIG. 1C illustrates a top view of the power module according to an aspect.

FIGS. 2A to 2D illustrate a manufacturing process for assembling the clip substrate member according to an aspect.

FIG. 3A illustrates a side view of a power module with a clip substrate member according to an aspect.

FIG. 3B illustrates a side view of a power module with a clip substrate member according to another aspect.

FIG. 4 illustrates an example of a power module with a clip substrate member according to another aspect.

FIG. 5 illustrates a flowchart depicting example operations of assembling a power module with a clip substrate member according to an aspect.

### DETAILED DESCRIPTION

The present disclosure relates to a power module that includes a substrate, a plurality of semiconductor dies, and a clip substrate member coupled to the plurality of semiconductor dies. The power module may include a single clip substrate member coupled to multiple semiconductor dies (e.g., two, three, or more than three semiconductor dies). The structure of the clip substrate member may reduce alignment issues (leading to shorter production items), reduce the size of the power module, and/or increase the thermal performance and mechanical reliability of the power module.

The clip substrate member includes a multi-material substrate having a conductive material and a dielectric material. In some examples, the clip substrate member includes a pre-molded printed circuit board with conductive and dielectric materials. The clip substrate member may electrically connect the plurality of semiconductor dies together (e.g., connect their source and gate terminals together). In some examples, drain terminals of the semiconductor dies are connected to the substrate.

The clip substrate member includes a first conductive clip, a second conductive clip, and a dielectric material with a portion that is disposed between the first conductive clip and the second conductive clip to electrically isolate the second conductive clip from the first conductive clip. A surface (e.g., a top surface) of the clip substrate member may define contact surfaces (e.g., source) that are used to connect to an external device. The contact surfaces are defined by the first and second conductive clips. In some examples, the contact surfaces may include a source contact region and a gate contact region. In some examples, the source contact region, defined on the surface of the clip substrate member, may include a relatively large area, which may increase the thermal performance and mechanical reliability of the power module. In some examples, the relatively large source contact region may increase drain-source on-resistance (RDS(on)) performance and/or junction-to-case thermal resistance (RthJF) performance.

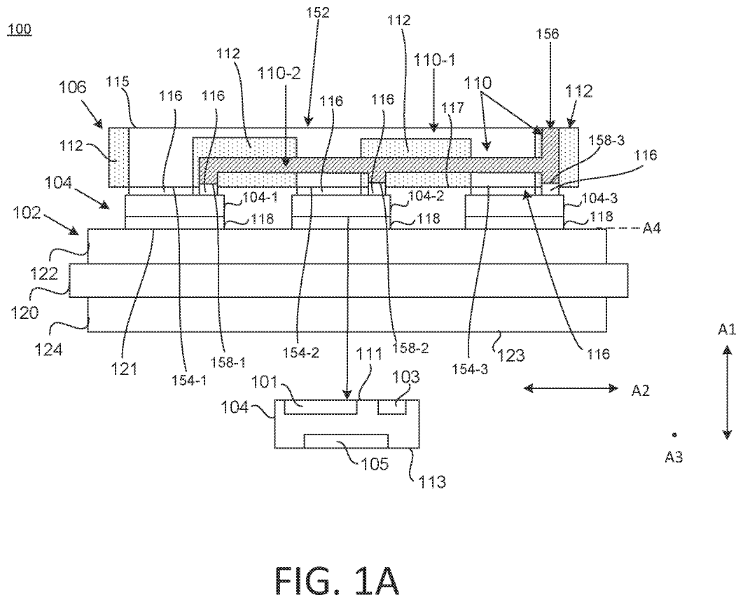

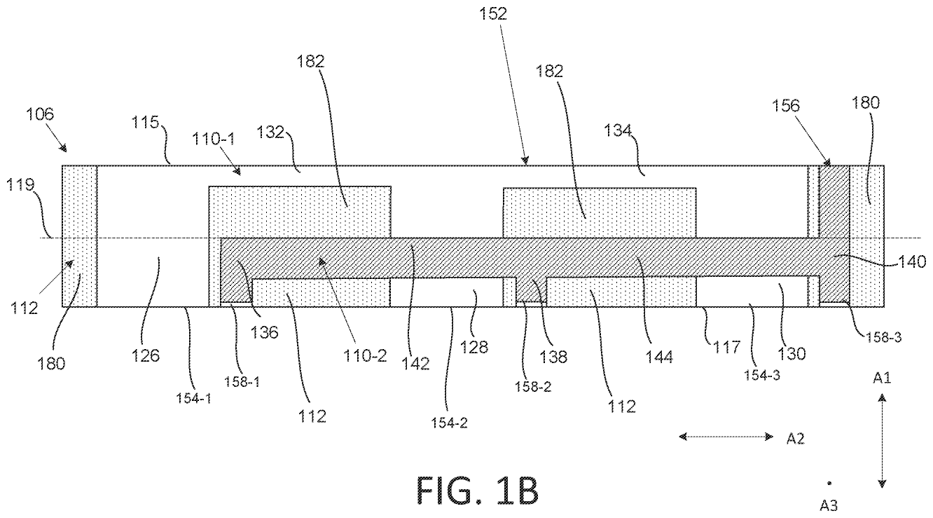

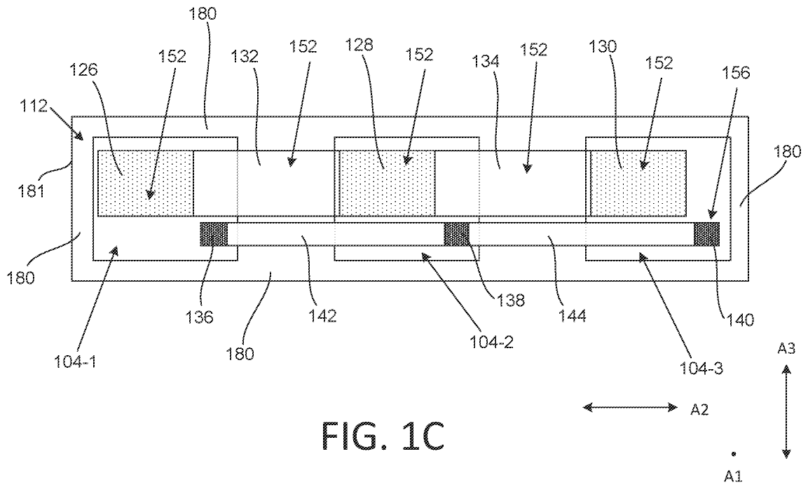

FIGS. 1A to 1C illustrate a power module 100 according to an aspect. The power module 100 includes a substrate 102, a plurality of semiconductor dies 104 coupled to the substrate 102, and a clip substrate member 106 coupled to the semiconductor dies 104. The clip substrate member 106 may be a multi-material substrate having a conductive material 110 and a dielectric material 112. In some examples, the power module 100 includes a single clip substrate member 106 coupled to three or more semiconductor dies 104. FIG. 1A illustrates a side view of the power module 100. FIG. 1B illustrates an enlarged side view of the clip substrate member 106. FIG. 1C illustrates a top view of the power module 100.

The substrate 102 includes a dielectric layer 120. The dielectric layer 120 includes an insulating material. In some examples, the dielectric layer 120 includes a ceramic material. In some examples, the substrate 102 includes a single dielectric layer 120. In some examples, the substrate 102 includes multiple dielectric layers 120. In some examples, the substrate 102 includes a printed circuit board (PCB) substrate (e.g., a single layer of PCB or multiple layers of PCB). In some examples, the substrate 102 includes a conductive layer 122 coupled to one surface of the dielectric layer 120, and a conductive layer 124 coupled to the other surface of the dielectric layer 120. In some examples, the conductive layer 122 includes a copper layer. In some examples, the conductive layer 124 includes a copper layer. In some examples, the substrate 102 is a direct bonded metal (DBM) substrate (e.g., a substrate with a dielectric disposed between two metal layers) such as a direct bonded copper (DBC) substrate.

The substrate 102 includes a first surface 121 and a second surface 123. In some examples, the first surface 121 is the surface (e.g., the top surface) of the conductive layer 122. In some examples, the second surface 123 is the other surface (e.g., the bottom surface) of the conductive layer 124. The second surface 123 may be disposed in parallel with the first surface 121. The distance between the first surface 121 and the second surface 123 may define the thickness of the substrate 102 in the direction A1. The first surface 121 is aligned in a plane A4. A direction A1 is aligned perpendicular to the plane A4, and a direction A2 is perpendicular to the direction A1. A direction A3 into the page (shown as a dot in FIGS. 1A and 1B) is aligned parallel to the plane A4 and is orthogonal to directions A1 and A2. The directions A1, A2, and A3, and plane A4, are used throughout several of the various views of the implementations described throughout the figures for simplicity.

The semiconductor dies 104 may include a semiconductor die 104-1, a semiconductor die 104-2, and a semiconductor die 104-3. Although three semiconductor dies 104 are depicted in FIGS. 1A to 1C, the number of semiconductor dies 104 may be two or any number greater than three such as four, five, six, seven, eight, etc. In some examples, the power module 100 includes three or more semiconductor dies 104. The semiconductor dies 104 are power semiconductor dies. A semiconductor die 104 includes a transistor. In some examples, a semiconductor die 104 includes a metal-oxide-semiconductor field-effect transistor (MOSFET). In some examples, a semiconductor die 104 includes an insulated-gate bipolar transistor (IGBT). In some examples, a semiconductor die 104 includes a thyristor. In some examples, the semiconductor dies 104 of multiple instances of the same type of transistor.

Each semiconductor die 104 includes a first surface 111 (e.g., a top surface) and a second surface 113 (e.g., a bottom surface). The first surface 111 and the second surface 113 may be aligned in a plane that is parallel to the plane A4. The distance between the first surface 111 and the second surface 113 defines a thickness of a semiconductor die 104 in the direction A1. Each semiconductor die 104 includes a source terminal 101, a gate terminal 103, and a drain terminal 105. The source terminal 101, the gate terminal 103, and the drain terminal 105 may be metalized regions in the semiconductor die 104. In some examples, for an IGT transistor, the source terminal 101 is referred to as a collector terminal. In some examples, for an IGT transistor, the drain terminal 105 is referred to as a collector terminal.

The semiconductor dies 104 are coupled to the substrate 102. The semiconductor dies 104 are coupled to the first surface 121 of the substrate 102. For example, the semiconductor dies 104 are coupled to the conductive layer 122 of the substrate 102 (e.g., the second surface 113 of the semiconductor dies 104 may be coupled to the conductive layer 122). The semiconductor dies 104 may be coupled to the conductive layer 122 using an adhesive material 118. The adhesive material 118 may be a die adhesive. The adhesive material 118 may include epoxy, silicone, and/or polyimide. As shown in FIG. 1A, the semiconductor die 104-1 is connected to the conductive layer 122 using an adhesive material 118, the semiconductor die 104-2 is connected to the conductive layer 122 using an adhesive material 118, and the semiconductor die 104-3 is connected to the conductive layer 122 using an adhesive material 118. In some examples, the drain terminal 105 of each semiconductor die 104 is connected to the substrate 102 (e.g., the conductive layer 122) via the adhesive material 118. For example, the semiconductor die 104-1, the semiconductor die 104-2, and the semiconductor die 104-3 are connected to the substrate 102 (e.g., the conductive layer 122 of the substrate 102).

The clip substrate member 106 is coupled to each of the semiconductor dies 104. In some examples, the clip substrate member 106 is coupled to the semiconductor dies 104 via die pads 116. A die pad 116 may be any type of conductive material and/or dielectric material, including metal, ceramic, and/or silicon. A die pad 116 may provide a physical and/or electrical connection between the semiconductor dies 104 and the clip substrate member 106. In some examples, the clip substrate member 106 is coupled to the first surface 111 of each semiconductor die 104 via one or more die pads 116. In some examples, a particular semiconductor die 104 is coupled to the clip substrate member 106 via two die pads 116 (e.g., one die pad 116 for the source connection and the other die pad 116 for the gate connection). The clip substrate member 106 includes a first surface 115 (e.g., a top surface) and a second surface 117 (e.g., a bottom surface). The distance between the first surface 115 and the second surface 117 defines the thickness of the clip substrate member 106. In some examples, the clip substrate member 106 has a rectangular shape (e.g., 3D rectangular shape) with a width and length defined along the directions A2 and A3 and a thickness defined along the direction A1.

The clip substrate member 106 may be a multi-material substrate having a conductive material 110 and a dielectric material 112. For example, the conductive material 110 may define a conductive clip 110-1 and a conductive clip 110-2. The conductive clip 110-1 and the conductive clip 110-2 may be conductive portions (e.g., metallic portions) that extend within and through the clip substrate member 106. The conductive clip 110-1 and the conductive clip 110-2 may include portions that connect to each semiconductor die 104. The dielectric material 112 includes one or more portions 182 disposed between the conductive clip 110-1 and the conductive clip 110-2. For example, portion(s) 182 of the dielectric material 112 may separate the conductive clip 110-1 from the conductive clip 110-2 in order to electrically isolate the conductive clip 110-1 and the conductive clip 110-2 from each other (e.g., electrically isolate the source and drain connections). The dielectric material 112 may define an outer perimeter 181 of the clip substrate member 106. For example, the dielectric material 112 may include a perimeter portion 180 that extends around and defines the sides of the clip substrate member 106 (e.g., the sides of the clip substrate member 106 being the surfaces that extends between the first surface 115 and the second surface 117 in the direction A1).

The conductive clip 110-1 is connected to each of the semiconductor dies 104. The conductive clip 110-1 is connected to the source terminal 101 (or emitter terminal) of each of the plurality of semiconductor dies 104. For example, the conductive clip 110-1 includes a surface region 154-1, which is exposed through the second surface 117 of the clip substrate member 106, and the surface region 154-1 is connected to the semiconductor die 104-1 (e.g., the source terminal 101 of the semiconductor die 104-1). In other words, a portion of the second surface 117 is (or defined by) the surface region 154-1, which is connected to the source terminal 101 of the semiconductor die 104-1 via a die pad 116.

The conductive clip 110-1 includes a surface region 154-2, which is exposed through the second surface 117 of the clip substrate member 106, and the surface region 154-2 is connected to the semiconductor die 104-2 (e.g., the source terminal 101 of the semiconductor die 104-2). In other words, another portion of the second surface 117 is (or defined by) the surface region 154-2, which is connected to the source terminal 101 of the semiconductor die 104-2 via a die pad 116. The conductive clip 110-1 includes a surface region 154-3, which is exposed through the second surface 117 of the clip substrate member 106, and the surface region 154-3 is connected to the semiconductor die 104-3 (e.g., the source terminal 101 of the semiconductor die 104-3). In other words, another portion of the second surface 117 is (or defined by) the surface region 154-3, which is connected to the source terminal 101 of the semiconductor die 104-3 via a die pad 116.

The conductive clip 110-1 defines a source contact region 152 on the first surface 115 of the clip substrate member 106. The source contact region 152 may be a contact region (e.g., surface region, contact pad, etc.) on the first surface 115, which is used to connect to an external component or device. In some examples, the source contact region 152, defined on the first surface 115 of the clip substrate member 106, may include a relatively large area, which may increase the thermal performance and mechanical reliability of the power module 100. In some examples, the source contact region 152 may increase drain-source on-resistance (RDS(on)) performance and/or junction-to-case thermal resistance (RthJF) performance. In some examples, the source contact region 152 is larger than a gate contact region 156 (which is also defined on the first surface 115).

As shown in FIG. 1B, the conductive clip 110-1 includes a portion 126 that extends between the surface region 154-1 and the source contact region 152 in the direction A1. In some examples, the portion 126 extends entirely through the thickness of the clip substrate member 106 in the direction A1. The conductive clip 110-1 includes a portion 128 that extends between the surface region 154-2 and the source contact region 152 in the direction A1. In some examples, the portion 128 extends entirely through the thickness of the clip substrate member 106 in the direction A1. The conductive clip 110-1 includes a portion 130 that extends between the surface region 154-3 and the source contact region 152 in the direction A1. In some examples, the portion 130 extends entirely through the thickness of the clip substrate member 106 in the direction A1.

The conductive clip 110-1 includes a portion 132 that extends between the portion 126 and the portion 128 in the direction A2. In some examples, the portion 132 connects the source terminal 101 of the semiconductor die 104-1 with the source terminal 101 of the semiconductor die 104-2. In some examples, the portion 132 extends along the first surface 115 of the clip substrate member 106 in the direction A2. The conductive clip 110-1 includes a portion 134 that extends between the portion 128 and the portion 130 in the direction A2. In some examples, the portion 134 connects the source terminal 101 of the semiconductor die 104-3 with the source terminal 101 of the semiconductor die 104-1 and the source terminal 101 of the semiconductor die 104-2. In some examples, the portion 134 extends along the first surface 115 of the clip substrate member 106 in the direction A2.

The second conductive clip 110-2 is connected to each of the semiconductor dies 104. The second conductive clip 110-2 is connected to the gate terminal 103 of each of the semiconductor dies 104. For example, the conductive clip 110-2 includes a surface region 158-1, which is exposed through the second surface 117 of the clip substrate member 106, and the surface region 158-1 is connected to the semiconductor die 104-1 (e.g., the gate terminal 103 of the semiconductor die 104-1). In other words, a portion of the second surface 117 is (or defined by) the surface region 158-1, which is connected to the gate terminal 103 of the semiconductor die 104-1 via a die pad 116. The conductive clip 110-2 includes a surface region 158-2, which is exposed through the second surface 117 of the clip substrate member 106, and the surface region 158-2 is connected to the semiconductor die 104-2 (e.g., the gate terminal 103 of the semiconductor die 104-2). In other words, another portion of the second surface 117 is (or defined by) the surface region 158-2, which is connected to the gate terminal 103 of the semiconductor die 104-2 via a die pad 116.

The conductive clip 110-2 includes a surface region 158-3, which is exposed through the second surface 117 of the clip substrate member 106, and the surface region 158-3 is connected to the semiconductor die 104-3 (e.g., the gate terminal 103 of the semiconductor die 104-3). In other words, another portion of the second surface 117 is (or defined by) the surface region 158-3, which is connected to the gate terminal 103 of the semiconductor die 104-3 via a die pad 116.

The conductive clip 110-2 defines a gate contact region 156 on the first surface 115 of the clip substrate member 106. The gate contact region 156 may be a contact region on the first surface 115, which is used to connect to an external component. In some examples, the size (e.g., surface area) of the gate contact region 156 (e.g., in the directions A2 and A3) on the first surface 115 of the clip substrate member 106 is smaller than the size (e.g., the surface area) of the source contact region 152 (e.g., in the directions A2 and A3). In other words, the size (e.g., the surface area) of the source contact region 152 on the first surface 115 of the clip substrate member 106 is greater than the size (e.g., the surface area) of the gate contact region 156 on the first surface 115. In some examples, the size (e.g., the surface area) of the source contact region 152 on the first surface 115 of the clip substrate member 106 is greater than twice the size (e.g., the surface area) of the gate contact region 156 on the first surface 115. In some examples, the size (e.g., the surface area) of the source contact region 152 on the first surface 115 is greater than three times the size (e.g., the surface area) of the gate contact region 156 on the first surface 115. In some examples, the size (e.g., the surface area) of the source contact region 152 on the first surface 115 is greater than four times the size (e.g., the surface area) of the gate contact region 156 on the first surface 115.

The conductive clip 110-2 includes a portion 136 that extends from the surface region 158-1 and into the clip substrate member 106 in the direction A1. In some examples, the portion 136 extends towards a central axis 119 of the clip substrate member 106. In some examples, the central axis 119 extends in the direction A2, and divides (e.g., equal divides) the clip substrate member 106 into two halves (e.g., a top half and a bottom half in the direction A1). In some examples, the portion 136 extends to the central axis 119 (e.g., contacts or interacts with the central axis 119). In some examples, the portion 136 extends only partially through the clip substrate member 106 in the direction A1. In some examples, the portion 136 does not extend into the top half of the clip substrate member 106. The conductive clip 110-2 includes a portion 138 that extends from the surface region 158-2 and into the clip substrate member 106 in the direction A1. In some examples, the portion 138 extends towards the central axis 119 in the direction A1. In some examples, the portion 138 extends to the central axis 119 (e.g., contacts or interacts with the central axis 119). In some examples, the portion 138 extends only partially through the clip substrate member 106 in the direction A1. In some examples, the portion 138 does not extend into the top half of the clip substrate member 106.

The conductive clip 110-2 includes a portion 140 that extends between the surface region 158-3 and the gate contact region 156 in the direction A1. In some examples, the portion 140 extends entirely through the thickness of the clip substrate member 106 in the direction A3. The conductive clip 110-2 includes a portion 142 that extends between the portion 136 and the portion 138 in the direction A2. In some examples, the portion 142 connects the gate terminal 103 of the semiconductor die 104-1 with the gate terminal 103 of the semiconductor die 104-2. The conductive clip 110-2 includes a portion 144 that extends between the portion 138 and the portion 140 in the direction A2. In some examples, the portion 144 connects the gate terminal 103 of the semiconductor die 104-3 with the gate terminal 103 of the semiconductor die 104-2 and the gate terminal 103 of the semiconductor die 104-1.

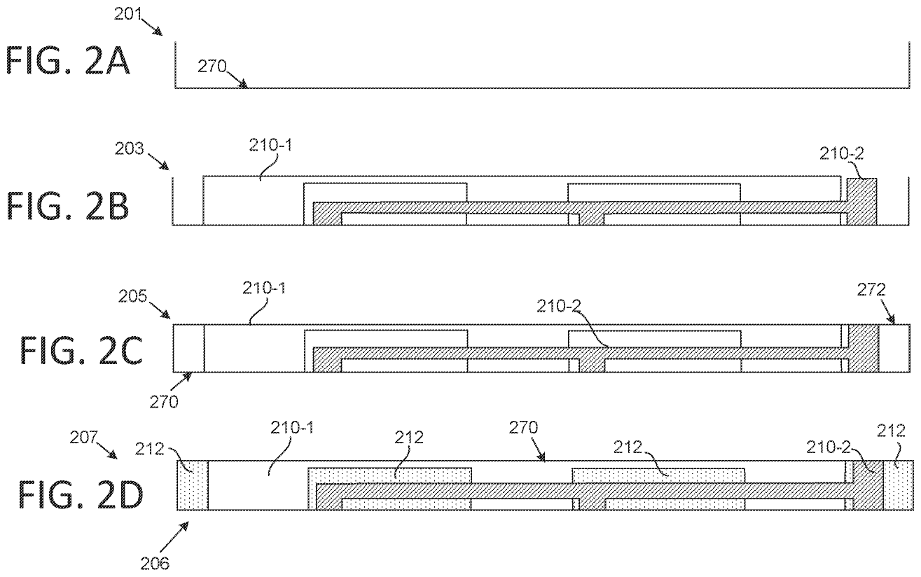

FIGS. 2A to 2D illustrate a manufacturing process of creating a clip substrate member 206 according to an aspect. The clip substrate member 206 may be an example of the clip substrate member 106 of FIGS. 1A to 1C and may include any of the details discussed with reference to those figures. Referring to FIG. 2A, operation 201 includes providing a mold cavity structure 270. A mold cavity structure 270 may be the part of an injection mold that is used to create the shape of the molded part. In some examples, the mold cavity structure 270 may define a cavity structure that is used to load the conductive clips (e.g., conductive clip 210-1 and conductive clip 210-2) and inject molding (e.g., dielectric material 212). Referring to FIG. 2B, operation 203 includes loading (e.g., inserting, placing, etc.) a conductive clip 210-1 and a conductive clip 210-2 into the mold cavity structure 270. Referring to FIG. 2C, operation 205 includes arranging (e.g., placing, coupling) a mold tool component 272 on the mold cavity structure 270. In some examples, the mold tool component 272 is referred to as a core. The mold tool component 272 may be aligned with the mold cavity structure 270 using guide pins and/or bushings.

Referring to FIG. 2D, operation 207 includes injecting a dielectric material 212 into the mold cavity structure 270. Operation 207 may also include curing the dielectric material 212, e.g., the process of hardening or toughening the material, which may include applying heat to the dielectric material 212 for a period of time. In some examples, operation 207 includes cutting (e.g., side cutting) the mold cavity structure 270. In some examples, operation 207 includes grinding the top and/or bottom surfaces to expose the metal portions of the conductive clip 210-1 and the conductive clip 210-2.

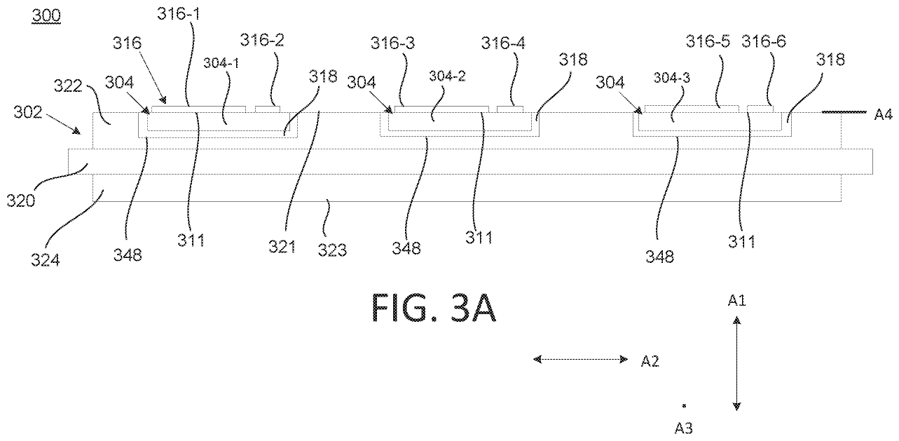

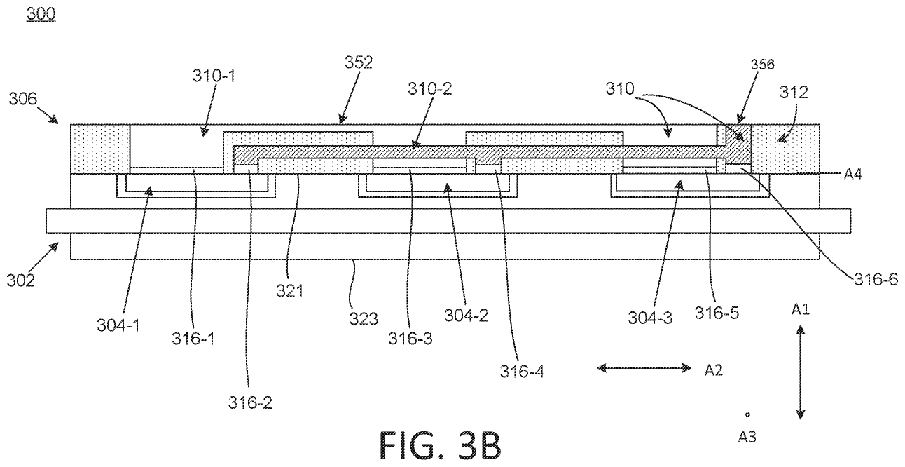

FIGS. 3A to 3B illustrate a power module 300 with a clip substrate member 306 according to an aspect. The power module 300 includes a substrate 302, a plurality of semiconductor dies 304 coupled to the substrate 302, and a clip substrate member 306 coupled to the semiconductor dies 304. The power module 300 and the clip substrate member 306 may be examples of the power module 100 and the clip substrate member 106 of FIGS. 1A to 1C and/or the clip substrate member 206 of FIGS. 2A to 2D and may include any of the details discussed with reference to those figures. In some examples, the substrate 302 includes recesses 348, which are used to hold the semiconductor dies 304.

The power module 300 includes a substrate 302 with a recess 348 for each semiconductor die 304. In some examples, a recess 348 is a depression (or a cut-out portion) in the substrate 302. In some examples, a recess 348 is a cavity or well that extends into the substrate 302 in the direction A1 from the first surface 321. The semiconductor dies 304 includes a semiconductor die 304-1, a semiconductor die 304-2, and a semiconductor die 304-3. The substrate 302 includes a conductive layer 322, a conductive layer 324, and a dielectric layer 320 disposed between the conductive layer 322 and the conductive layer 324.

The substrate 302 includes a first surface 321 and a second surface 323. In some examples, the first surface 321 is the surface (e.g., the top surface) of the conductive layer 322. In some examples, the second surface 323 is the other surface (e.g., the bottom surface) of the conductive layer 324. The second surface 323 may be disposed in parallel with the first surface 321. The distance between the first surface 321 and the second surface 323 may define the thickness of the substrate 302 in the direction A1. The first surface 321 is aligned in a plane A4. A direction A1 is aligned perpendicular to the plane A4, and a direction A2 is perpendicular to the direction A1. A direction A3 into the page (shown as a dot in FIG. 3A) is aligned parallel to the plane A4 and is orthogonal to directions A1 and A2.

The conductive layer 322 includes a plurality of recesses 348. A particular semiconductor die 304 is inserted into a separate recess 348. The semiconductor die 304-1 is disposed within a recess 348 and coupled to the conductive layer 322 using an adhesive material 318. The semiconductor die 304-2 is disposed within a separate recess 348 and coupled to the conductive layer 322 using an adhesive material 318. The semiconductor die 304-3 is disposed within another recess 348 and coupled to the conductive layer 322 using an adhesive material 318. In some examples, a surface 311 (e.g., a top surface) of a semiconductor die 304 is aligned with the first surface 321 (e.g., the top surface) of the substrate 302 in the direction A1. In some examples, the surface 311 is below the first surface 321 in the direction A1. The power module 300 includes a plurality of die pads 316 coupled to the semiconductor dies 304. For example, a die pad 316-1 and a die pad 316-2 are coupled to the semiconductor die 304-1. A die pad 316-3 and a die pad 316-4 are coupled to the semiconductor die 304-2. A die pad 316-5 and a die pad 316-6 are coupled to the semiconductor die 304-3. The die pads 316 are used to connect to the clip substrate member 306.

Referring to FIG. 3B, the clip substrate member 306 is coupled to the semiconductor dies 306. For example, the clip substrate member 306 is coupled to the semiconductor die 304-1, the semiconductor die 304-2, and the semiconductor die 304-3. The clip substrate member 306 may be an example of the clip substrate member 106 of FIGS. 1A to 1C and/or the clip substrate member 206 of FIGS. 2A to 2D and may include any of the details with reference to those figures. For example, the clip substrate member 306 may be a multi-material substrate having a conductive material 310 and a dielectric material 312. In some examples, the power module 300 includes a single clip substrate member 306 coupled to three or more semiconductor dies 304. The clip substrate member 306 includes a conductive clip 310-1 connected to the die paid 316-1, the die pad 316-3, and the die pad 316-5. The clip substrate member 30 includes a conductive clip 310-2 connected to the die paid 316-2, the die pad 316-4, and the die pad 316-6. Also, the clip substrate member 306 includes a source contact region 352 defined by the conductive clip 310-1 and a gate contact region 356 defined by the conductive clip 310-2.

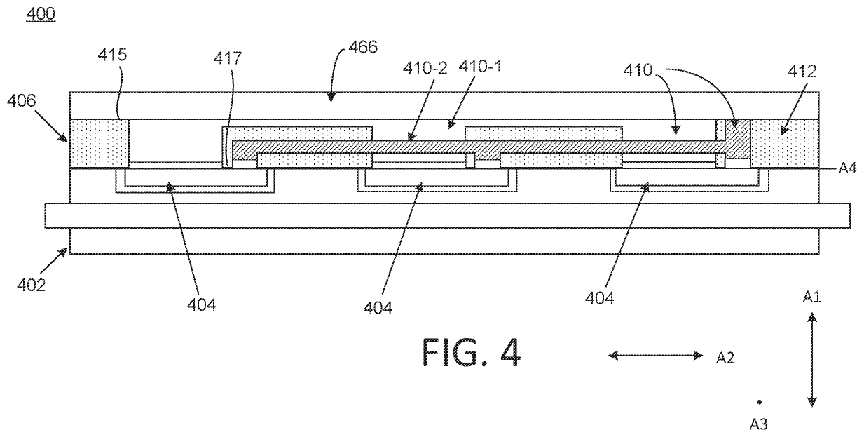

FIG. 4 illustrates a power module 400 with a clip substrate member 406. The power module 400 may be an example of the power module 100 of FIGS. 1A to 1C and/or the power module 300 of FIGS. 3A and 3B and may include any of the details discussed herein. The power module 400 includes a substrate 402, a plurality of semiconductor dies 404 coupled to the substrate 402, and a clip substrate member 406 coupled to the semiconductor dies 404. As shown in FIG. 4, the power module 400 includes a substrate 466 coupled to the clip substrate member 406.

The clip substrate member 406 includes a conductive material 410 and a dielectric material 412. The conductive material 410 includes a conductive clip 410-1 and a conductive clip 410-2. The dielectric material 412 includes a portion disposed between the conductive clip 410-1 and the conductive clip 410-2. The clip substrate member 406 includes a first surface 415 (e.g., a top surface) and a second surface 417 (e.g., a bottom surface). The power module 400 includes a substrate 466 coupled to the clip substrate member 406. In some examples, the substrate 466 includes a dielectric substrate. In some examples, the substrate 466 includes a substrate that is similar or the same as substrate 402. In some examples, the substrate 466 includes a DBC substrate.

Clause 1. A power module comprising: a substrate; a plurality of semiconductor dies coupled to the substrate; and a clip substrate member having a first surface and a second surface, the first surface being coupled to the plurality of semiconductor dies, the clip substrate member including a first conductive clip, and a second conductive clip, and a dielectric material portion disposed between the first conductive clip and the second conductive clip, the second surface including a first contact region and a second contact region, the first contact region including a portion of the first conductive clip, the second contact region including a portion of the second conductive clip.

Clause 2. The power module of clause 1, wherein the first conductive clip is connected to a source terminal of each of the plurality of semiconductor dies.

Clause 3. The power module of clause 1 or 2, wherein the second conductive clip is connected to a gate terminal of each of the plurality of semiconductor dies.

Clause 4. The power module of any of clauses 1 to 3, wherein each of the plurality of semiconductor dies includes a drain terminal connected to the substrate.

Clause 5. The power module of any of clauses 1 to 4, wherein the substrate includes a first conductive layer, a second conductive layer, and a dielectric layer disposed between the first conductive layer and the second conductive layer.

Clause 6. The power module of any of clauses 1 to 5, wherein the first contact region has a size greater than a size of the second contact region.

Clause 7. The power module of any of clauses 1 to 6, wherein the first contact region is a source contact for an external device, and the second contact region is a gate contact for the external device.

Clause 8. The power module of any of clauses 1 to 7, wherein the plurality of semiconductor dies includes a first semiconductor die, a second semiconductor die, and a third semiconductor die.

Clause 9. The power module of any of clauses 1 to 8, wherein the clip substrate member is connected to each of the plurality of semiconductor dies via a die pad.

Clause 10. The power module of any of clauses 1 to 9, wherein the clip substrate member includes a plurality of recesses and each of the plurality of semiconductor dies is included in a separate recess of the plurality of recesses.

Clause 11. The power module of any of clauses 1 to 10, wherein the substrate is a first substrate, the power module further comprising: a second substrate coupled to the clip substrate member.

Clause 12. A power module comprising: a substrate including a first conductive layer, a second conductive layer, and a dielectric layer disposed between the first conductive layer and the second conductive layer; a plurality of semiconductor dies coupled to the first conductive layer of the substrate; and a clip substrate member including a first conductive clip coupled to the plurality of semiconductor dies, a second conductive clip coupled to the plurality of semiconductor dies, and a dielectric material having a portion disposed between the first conductive clip and the second conductive clip, the clip substrate member including a source contact region, the source contact region including a first portion of a surface of the clip substrate member, the source contact region including a portion of the first conductive clip.

Clause 13. The power module of clause 12, wherein the clip substrate member includes a gate contact region, the gate contact region including a second portion of the surface of the clip substrate member, the gate contact region including a portion of the second conductive clip.

Clause 14. The power module of clause 13, wherein the source contact region has a size greater than a size of the gate contact region.

Clause 15. The power module of any of clauses 12 to 14, wherein the first conductive clip is connected to a source terminal of each of the plurality of semiconductor dies, the second conductive clip being connected to a gate terminal of each of the plurality of semiconductor dies.

Clause 16. The power module of any of clauses 12 to 15, wherein the plurality of semiconductor dies includes a first semiconductor die, a second semiconductor die, and a third semiconductor die, the clip substrate member including a first recess with the first semiconductor die, a second recess with the second semiconductor die, and a third recess with the third semiconductor die.

Clause 17. A method of assembling a power module, the method comprising; assembling a clip substrate member, the clip substrate member including a first conductive clip, a second conductive clip, and a dielectric material having a portion disposed between the first conductive clip and the second conductive clip, the clip substrate member including a first surface and a second surface; coupling a plurality of semiconductor dies to a conductive layer of a substrate; and coupling the clip substrate member to the plurality of semiconductor dies such that the plurality of semiconductor dies is coupled to the first conductive clip and the second conductive clip.

Clause 18. The method of clause 17, wherein the clip substrate member includes a source contact region and a gate contact region, the source contact region including a first portion of a surface of the clip substrate member, the gate contact region including a second portion of the surface of the clip substrate member, the source contact region including a portion of the first conductive clip, the gate contact region including a portion of the second conductive clip.

Clause 19. The method of clause 17 or 18, further comprising: creating a plurality of recesses in the substrate; disposing the plurality of semiconductor dies in the plurality of recesses; and coupling the plurality of semiconductor dies to the substrate using a die adhesive material.

Clause 20. The method of any of clauses 17 to 19, wherein assembling the clip substrate member includes: arranging the first conductive clip and the second conductive clip in a mold cavity structure; and injecting the dielectric material in the mold cavity structure.

It will be understood that, in the foregoing description, when an element is referred to as being connected to, electrically connected to, coupled to, or electrically coupled to another element, it may be directly connected or coupled to the other element, or one or more intervening elements may be present. In contrast, when an element is referred to as being directly connected to or directly coupled to another element, there are no intervening elements. Although the terms directly connected to, or directly coupled to may not be used throughout the detailed description, elements that are shown as being directly connected or directly coupled can be referred to as such. The claims of the application, if any, may be amended to recite exemplary relationships described in the specification or shown in the figures. Implementations of the various techniques described herein may be implemented in (e.g., included in) digital electronic circuitry, or in computer hardware, firmware, software, or in combinations of them. Portions of methods also may be performed by, and an apparatus may be implemented as, special purpose logic circuitry, e.g., an FPGA (field programmable gate array) or an ASIC (application specific integrated circuit).

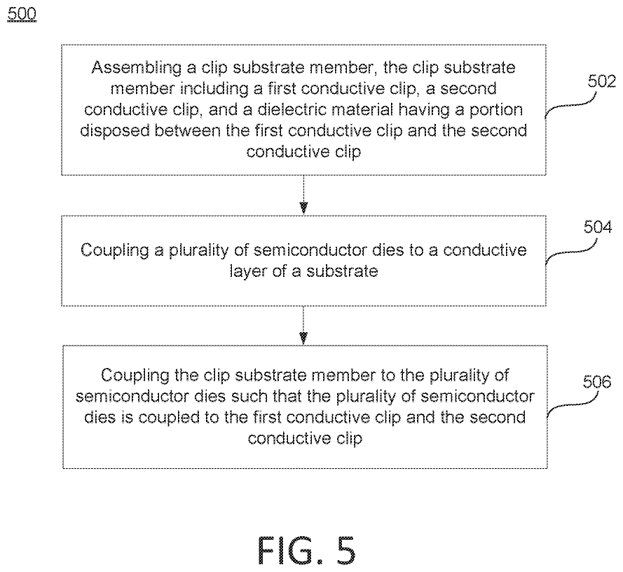

FIG. 5 depicts a flowchart 500 depicting example operations for a method of assembling a power module. Although the flowchart 500 is described with reference to the power module 100 of FIGS. 1A to 1C, the flowchart may be applicable to any of the power modules discussed herein. Although the flowchart 500 of FIG. 5 illustrates operations in sequential order, it will be appreciated that this is merely an example, and that additional or alternative operations may be included. Further, operations of FIG. 5 and related operations may be executed in a different order than that shown, or in a parallel or overlapping fashion.

Operation 502 includes assembling a clip substrate member 106, the clip substrate member 106 including a first conductive clip (e.g., conductive clip 110-1), a second conductive clip (e.g., conductive clip 110-2), and a dielectric material 112 having a portion 182 disposed between the first conductive clip and the second conductive clip. Operation 504 includes coupling a plurality of semiconductor dies 104 to a conductive layer 122 of a substrate 102. Operation 506 includes coupling the clip substrate member 106 to the plurality of semiconductor dies 104 such that the plurality of semiconductor dies 104 is coupled to the first conductive clip and the second conductive clip.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. A power module comprising:
a substrate;
a plurality of semiconductor dies coupled to the substrate; and
a clip substrate member having a first surface and a second surface, the first surface being coupled to the plurality of semiconductor dies, the clip substrate member including a first conductive clip, and a second conductive clip, and a dielectric material portion disposed between the first conductive clip and the second conductive clip,
the second surface including a first contact region and a second contact region, the first contact region including a portion of the first conductive clip, the second contact region including a portion of the second conductive clip.

2. The power module of claim 1, wherein the first conductive clip is connected to a source terminal of each of the plurality of semiconductor dies.

3. The power module of claim 1, wherein the second conductive clip is connected to a gate terminal of each of the plurality of semiconductor dies.

4. The power module of claim 1, wherein each of the plurality of semiconductor dies includes a drain terminal connected to the substrate.

5. The power module of claim 1, wherein the substrate includes a first conductive layer, a second conductive layer, and a dielectric layer disposed between the first conductive layer and the second conductive layer.

6. The power module of claim 1, wherein the first contact region has a size greater than a size of the second contact region.

7. The power module of claim 1, wherein the first contact region is a source contact for an external device, and the second contact region is a gate contact for the external device.

8. The power module of claim 1, wherein the plurality of semiconductor dies includes a first semiconductor die, a second semiconductor die, and a third semiconductor die.

9. The power module of claim 1, wherein the clip substrate member is connected to each of the plurality of semiconductor dies via a die pad.

10. The power module of claim 1, wherein the clip substrate member includes a plurality of recesses and each of the plurality of semiconductor dies is included in a separate recess of the plurality of recesses.

11. The power module of claim 1, wherein the substrate is a first substrate, the power module further comprising:
a second substrate coupled to the clip substrate member.

12. A power module comprising:
a substrate including a first conductive layer, a second conductive layer, and a dielectric layer disposed between the first conductive layer and the second conductive layer;
a plurality of semiconductor dies coupled to the first conductive layer of the substrate; and
a clip substrate member including a first conductive clip coupled to the plurality of semiconductor dies, a second conductive clip coupled to the plurality of semiconductor dies, and a dielectric material having a portion disposed between the first conductive clip and the second conductive clip,
the clip substrate member including a source contact region, the source contact region including a first portion of a surface of the clip substrate member, the source contact region including a portion of the first conductive clip.

13. The power module of claim 12, wherein the clip substrate member includes a gate contact region, the gate contact region including a second portion of the surface of the clip substrate member, the gate contact region including a portion of the second conductive clip.

14. The power module of claim 13, wherein the source contact region has a size greater than a size of the gate contact region.

15. The power module of claim 12, wherein the first conductive clip is connected to a source terminal of each of the plurality of semiconductor dies, the second conductive clip being connected to a gate terminal of each of the plurality of semiconductor dies.

16. The power module of claim 12, wherein the plurality of semiconductor dies includes a first semiconductor die, a second semiconductor die, and a third semiconductor die, the clip substrate member including a first recess with the first semiconductor die, a second recess with the second semiconductor die, and a third recess with the third semiconductor die.

17. A method of assembling a power module, the method comprising;
assembling a clip substrate member, the clip substrate member including a first conductive clip, a second conductive clip, and a dielectric material having a portion disposed between the first conductive clip and the second conductive clip, the clip substrate member including a first surface and a second surface;
coupling a plurality of semiconductor dies to a conductive layer of a substrate; and
coupling the clip substrate member to the plurality of semiconductor dies such that the plurality of semiconductor dies is coupled to the first conductive clip and the second conductive clip.

18. The method of claim 17, wherein the clip substrate member includes a source contact region and a gate contact region, the source contact region including a first portion of a surface of the clip substrate member, the gate contact region including a second portion of the surface of the clip substrate member, the source contact region including a portion of the first conductive clip, the gate contact region including a portion of the second conductive clip.

19. The method of claim 17, further comprising:
creating a plurality of recesses in the substrate;
disposing the plurality of semiconductor dies in the plurality of recesses; and
coupling the plurality of semiconductor dies to the substrate using a die adhesive material.

20. The method of claim 17, wherein assembling the clip substrate member includes:
arranging the first conductive clip and the second conductive clip in a mold cavity structure; and
injecting the dielectric material in the mold cavity structure.
